(19) United States
(12) Patent Application Publication
(10) Pub. No.: US 2019/0250477 A1
(43) Pub. Date: Aug. 15, 2019

(54) ARRAY SUBSTRATE AND DISPLAY DEVICE

(71) Applicant: Wuhan China Star Optoelectronics Technology Co., Ltd., Wuhan (CN)

(72) Inventors: Bingkun YIN, Wuhan (CN); Hungming SHEN, Wuhan (CN)

(21) Appl. No.: 16/152,307

(22) Filed: Oct. 4, 2018

Related U.S. Application Data
(63) Continuation of application No. PCT/CN2018/095693, filed on Jul. 13, 2018.

(30) Foreign Application Priority Data
Feb. 9, 2018 (CN) 201810134546.4

(51) Int. Cl. G02F 1/1362; H01L 27/12; G02F 1/1339

(52) U.S. Cl. CPC G02F 1/136286; H01L 27/124; G02F 1/133514; G02F 1/136227; G02F 1/13394

(57) ABSTRACT

Provided is an array substrate, including a main body, a sealant coating region formed on a periphery of the main body and used for sealant coating and a liquid crystal filling region located in a middle of the main body and surrounded by the sealant coating region; in the sealant coating region, a metal trace structure on the main body is provided, and includes metal traces spaced apart; wherein the sealant coating region comprises light transmissive regions between the metal traces; in a region of the sealant coating region adjacent to the liquid crystal filling region, a proportion of the light transmissive region adjacent to the liquid crystal filling region is larger than a proportion of the light transmissive region away from the liquid crystal filling region; the proportion of the light transmissive region is an area ratio of the light transmissive region to a corresponding sealant coating region.

### CROSS-REFERENCE TO RELATED APPLICATION

This application is a continuing application of PCT Patent Application No. PCT/CN2018/095693 entitled “Array substrate and display device”, filed on Jul. 13, 2018, which claims priority to Chinese Patent Application No. 201810134546.4, filed on Feb. 9, 2018, both of which are hereby incorporated in its entireties by reference.

### FIELD OF THE INVENTION

The present invention relates to a display field, and more particularly to an array substrate and a display device.

### BACKGROUND OF THE INVENTION

The liquid crystal display device usually includes a color film substrate, an array substrate and a liquid crystal filled between the color filter substrate and the array substrate and a sealant. The sealant is coated on the color film substrate or the array substrate, and is distributed near the peripheral edges of the color filter substrate and the array substrate. The color film substrate and the array substrate are combined to form a liquid crystal cell by the sealant curing to maintain the cell thickness between the color filter substrate and the array substrate, and the sealing of the liquid crystal cell can be realized to cut off contact between the liquid crystal molecules and the outside.

The curing of the sealant generally requires two processes of UV curing and heat curing. If the sealant is cured abnormally, the sealant that is not fully cured will cause contamination of the liquid crystal. In the prior art, in order to reduce the contamination of the liquid crystal by the sealant, it is required that the design of the metal traces in the sealant possesses a higher aperture ratio, but the contamination influence of the position of the sealant coating and the position of the metal traces to the liquid crystal is rarely considered. However, as the resolution of the display device increases, the aperture ratio of the sealant will become smaller and smaller. If the cure rate of the sealant is intended to be decreased only by improving the aperture ratio of the sealant for reducing the contamination of the liquid crystal, it must more and more difficult.

Therefore, there is a need to optimize the design of the metal traces of the sealant adjacent to the liquid crystal to improve the curing rate of the sealant adjacent to the liquid crystal, so as to reduce the contamination of the liquid crystal by the incompletely cured sealant.

### SUMMARY OF THE INVENTION

An objective of the present invention is to provide an array substrate and a display device to optimize the design of the metal traces of the sealant adjacent to the liquid crystal to improve the curing rate of the sealant adjacent to the liquid crystal, so as to reduce the contamination of the liquid crystal by the incompletely cured sealant.

For solving the aforesaid technical issues, the embodiment of the present invention provides an array substrate, comprising a main body, a sealant coating region formed on a periphery of the main body and used for sealant coating or curing, and a liquid crystal filling region located in a middle of the main body and surrounded by the sealant coating region; wherein

in the sealant coating region, a metal trace structure on the main body is provided, and the metal trace structure comprises a plurality of metal traces spaced apart; wherein the sealant coating region comprises light transmissive regions corresponding to gaps between the plurality of metal traces;

in a region of the sealant coating region adjacent to a side of the liquid crystal filling region, a proportion of the light transmissive region adjacent to the liquid crystal filling region is larger than a proportion of the light transmissive region away from the liquid crystal filling region; wherein the proportion of the light transmissive region is an area ratio of the light transmissive region to a corresponding sealant coating region.

Widths of the plurality of metal traces in the metal trace structure are decreased progressively by a linear decreasing law or a nonlinear decreasing law in a direction from the metal trace structure toward the liquid crystal filling region, and spacings between every two adjacent metal traces in the metal trace structure are equal.

Each of the plurality of metal traces in the metal trace structure comprises a metal trace of a single layer structure; or

each of the plurality of metal traces in the metal trace structure comprises a combination of a metal trace of a single layer structure and a metal trace of a laminated layers structure; or

each of the plurality of metal traces in the metal trace structure comprises a metal trace of a laminated layers structure.

The array substrate further comprises a sealant being coated on the sealant coating region of the main body and covering the metal trace structure.

The main body comprises a first substrate, a first metal layer, a gate insulating layer, an active layer, a second metal layer, a passivation layer and a pixel electrode layer, which are sequentially disposed from bottom to top.

Correspondingly, the embodiment of the present invention further provides an array substrate, comprising a main body, a sealant coating region formed on a periphery of the main body and used for sealant coating and a liquid crystal filling region located in a middle of the main body and surrounded by the sealant coating region; wherein

in the sealant coating region, a metal trace structure on the main body is provided, and the metal trace structure comprises a plurality of metal traces spaced apart; wherein the sealant coating region comprises light transmissive regions corresponding to gaps between the plurality of metal traces;

in a region of the sealant coating region adjacent to a side of the liquid crystal filling region, a proportion of the light transmissive region adjacent to the liquid crystal filling region is larger than a proportion of the light transmissive region away from the liquid crystal filling region; wherein the proportion of the light transmissive region is an area ratio of the light transmissive region to a corresponding sealant coating region;

wherein widths of the plurality of metal traces in the metal trace structure are equal, and spacings between every two adjacent metal traces in the metal trace structure are increased progressively by a linear increasing law or a nonlinear increasing law in a direction from the metal trace structure toward the liquid crystal filling region; or

the widths of the plurality of metal traces in the metal trace structure are decreased progressively by a linear decreasing law or a nonlinear decreasing law in a direction from the metal trace structure toward the liquid crystal filling region, and spacings between every two adjacent metal traces in the metal trace structure are increased progressively by a linear increasing law or a nonlinear increasing law in a direction from the metal trace structure toward the liquid crystal filling region.

Each of the plurality of metal traces in the metal trace structure comprises a metal trace of a single layer structure; or

each of the plurality of metal traces in the metal trace structure comprises a combination of a metal trace of a single layer structure and a metal trace of a laminated layers structure; or

each of the plurality of metal traces in the metal trace structure comprises a metal trace of a laminated layers structure.

The array substrate further comprises a sealant being coated on the sealant coating region of the main body and covering the metal trace structure.

The main body comprises a first substrate; a first metal layer, a gate insulating layer, an active layer, a second metal layer, a passivation layer and a pixel electrode layer, which are sequentially disposed from bottom to top.

Correspondingly, the embodiment of the present invention further provides a display device, comprising an array substrate and a color filter substrate; wherein

the array substrate comprises a main body, a sealant coating region formed on a periphery of the main body and used for sealant coating and a liquid crystal filling region located in a middle of the main body and surrounded by the sealant coating region; wherein

in the sealant coating region, a metal trace structure on the main body is provided, and the metal trace structure comprises a plurality of metal traces spaced apart; wherein the sealant coating region comprises light transmissive regions corresponding to gaps between the plurality of metal traces;

in a region of the sealant coating region adjacent to a side of the liquid crystal filling region, a proportion of the light transmissive region adjacent to the liquid crystal filling region is larger than a proportion of the light transmissive region away from the liquid crystal filling region; wherein the proportion of the light transmissive region is an area ratio of the light transmissive region to a corresponding sealant coating region.

Widths of the plurality of metal traces in the metal trace structure are decreased progressively by a linear decreasing law or a nonlinear decreasing law in a direction from the metal trace structure toward the liquid crystal filling region, and spacings between every two adjacent metal traces in the metal trace structure are equal.

Each of the plurality of metal traces in the metal trace structure comprises a metal trace of a single layer structure.

Widths of the plurality of metal traces in the metal trace structure are equal, and spacings between every two adjacent metal traces in the metal trace structure are increased progressively by a linear increasing law or a nonlinear increasing law in a direction from the metal trace structure toward the liquid crystal filling region.

Each of the plurality of metal traces in the metal trace structure comprises a combination of a metal trace of a single layer structure and a metal trace of a laminated layers structure.

The widths of the plurality of metal traces in the metal trace structure are decreased progressively by a linear decreasing law or a nonlinear decreasing law in a direction from the metal trace structure toward the liquid crystal filling region, and spacings between every two adjacent metal traces in the metal trace structure are increased progressively by a linear increasing law or a nonlinear increasing law in a direction from the metal trace structure toward the liquid crystal filling region.

Each of the plurality of metal traces in the metal trace structure comprises a metal trace of a single layer structure.

The color filter substrate comprises a second substrate, and a black matrix, a color filter layer and a metal electrode layer located on the second substrate.

The color filter layer comprises a red color resist layer, a green color resist layer and a blue color resist layer.

In summary, the implementation of the embodiments of the present invention possesses the following beneficial result; in the case where the total designed width of the sealant coating region is limited, the proportion of the light transmissive region is improved by increasing the spacings of metal traces of the sealant adjacent to the liquid crystal (the spacings of the metal traces are increased progressively by a linear increasing law or a nonlinear increasing law in a direction from the metal trace structure toward the liquid crystal filling region) or reducing the widths of the metal traces adjacent to the liquid crystal (the widths of the metal traces are decreased progressively by a linear increasing law or a nonlinear increasing law in a direction from the metal trace structure toward the liquid crystal filling region). Thus, the UV light (ultraviolet light) transmittance adjacent to the liquid crystal is improved to increase the curing rate of the sealant adjacent to the liquid crystal, so as to reduce the contamination of the liquid crystal by the incompletely cured sealant.

### BRIEF DESCRIPTION OF THE DRAWINGS

In order to more clearly illustrate the embodiments of the present invention or prior art, the following figures will be described in the embodiments are briefly introduced. It is obvious that the drawings are merely some embodiments of the present invention, those of ordinary skill in this field can obtain other figures according to these figures without paying the premise.

FIG. 1 is a partial cross-sectional view diagram of an array substrate according to the first embodiment of the present invention;

FIG. 2 is a partial plan view diagram of a light shielding region and a light transmissive region projected by a metal trace structure in an array substrate which is projected on a sealant coating region according to the first embodiment of the present invention;

FIG. 3 is a schematic planar structure diagram of a metal trace structure in an array substrate according to the first embodiment of the present invention;

FIG. 4 is another schematic planar structure diagram of a metal trace structure in an array substrate according to the first embodiment of the present invention;

FIG. 5 is one another schematic planar structure diagram of a metal trace structure in an array substrate according to the first embodiment of the present invention;

FIG. 6 is one another schematic planar structure diagram of a metal trace structure in an array substrate according to the first embodiment of the present invention;

FIG. 7 is one another schematic planar structure diagram of a metal trace structure in an array substrate according to the first embodiment of the present invention;

FIG. 8 is one another schematic planar structure diagram of a metal trace structure in an array substrate according to the first embodiment of the present invention;

FIG. 9 is a partial cross-sectional view diagram of a display device according to the second embodiment of the present invention.

### DETAILED DESCRIPTION OF PREFERRED EMBODIMENTS

In order to make the objectives, technical solutions, and advantages of the embodiments of the disclosure more apparent; the present invention will be described below in detail with reference to the drawings.

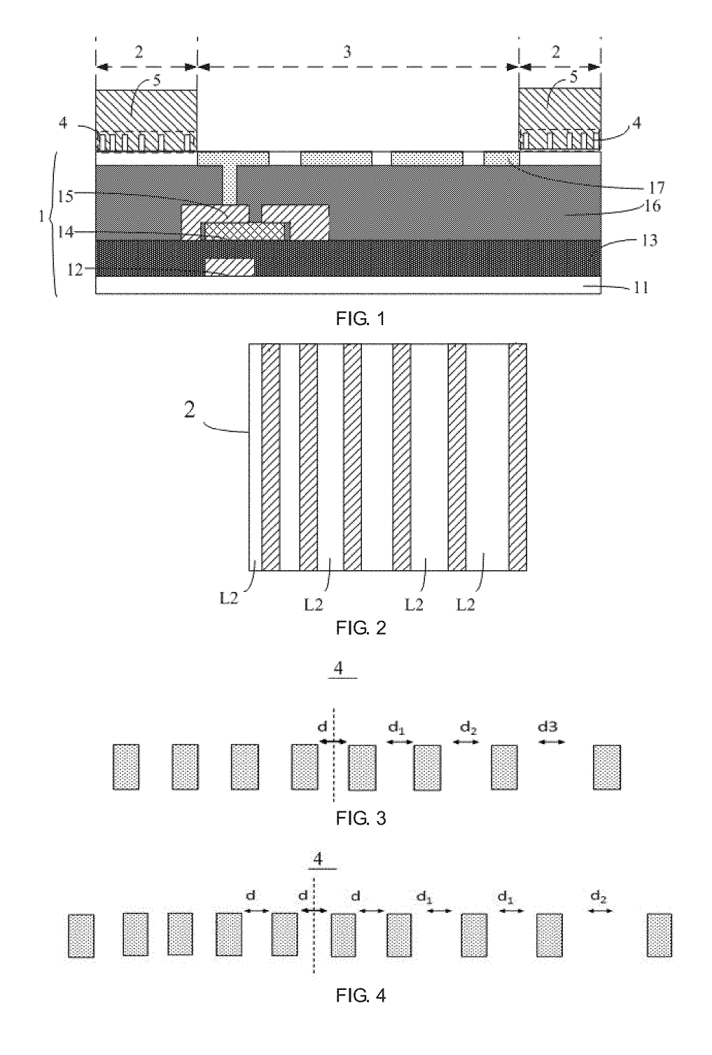

As shown in FIG. 1 and FIG. 2; the first embodiment of the present invention provides an array substrate; comprising a main body 1, a sealant coating region 2 formed on the main body 1 and on a periphery of the main body 1 and used for sealant coating and a liquid crystal filling region 3 located in a middle of the main body 1 and surrounded by the sealant coating region 2; wherein

in the sealant coating region 2, a metal trace structure 4 on the main body 1 is provided, and the metal trace structure 4 comprises a plurality of metal traces spaced apart; wherein the sealant coating region 2 comprises light transmissive regions corresponding to gaps between the plurality of metal traces;

in a region of the sealant coating region 2 adjacent to a side of the liquid crystal filling region 3, a proportion of the light transmissive region L2 adjacent to the liquid crystal filling region 3 is larger than a proportion of the light transmissive region L2 away from the liquid crystal filling region 3; wherein the proportion of the light transmissive region L2 is an area ratio of the light transmissive region L2 to a corresponding sealant coating region 2.

It should be noted that the larger the ratio of the light transmissive region L2 is, the higher the UV light transmittance is. Therefore, in the region of the sealant coating region 2 adjacent to the liquid crystal filling region 3, the proportion of the light transmissive region adjacent to the liquid crystal filling region 3 is larger than the proportion of the light transmissive region away from the liquid crystal filling region 3. Thus, compared with the tracing rule of the conventional metal trace structure 4, the area of the light transmissive region L2 formed by the metal trace in the sealant coating region 2 is gradually increased, so that the area of the light transmissive region L2 is increased. Particularly, in the sealant coating region 2 adjacent to the liquid crystal filling region 3, it can be seen more obvious.

In the first embodiment of the present invention, in the case where the total designed width of the sealant coating region 2 is limited, the proportion of the light transmissive region L2 is improved by increasing the spacings of metal traces of the sealant adjacent to the liquid crystal or reducing the widths of the metal traces adjacent to the liquid crystal. Thus, the UV light transmittance adjacent to the liquid crystal is improved to increase the curing rate of the sealant adjacent to the liquid crystal, so as to reduce the contamination of the liquid crystal by the incompletely cured sealant.

In one embodiment, widths of the plurality of metal traces in the metal trace structure 4 are decreased progressively by a linear decreasing law or a nonlinear decreasing law in a direction from the metal trace structure 4 toward the liquid crystal filling region 3, and spacings between every two adjacent metal traces in the metal trace structure 4 are equal.

In another embodiment, the widths of the plurality of metal traces in the metal trace structure 4 are equal, and spacings between every two adjacent metal traces in the metal trace structure 4 are increased progressively by a linear increasing law or a nonlinear increasing law in a direction from the metal trace structure 4 toward the liquid crystal filling region 3.

In another embodiment, the widths of the plurality of metal traces in the metal trace structure 4 are decreased progressively by a linear decreasing law or a nonlinear decreasing law in a direction from the metal trace structure 4 toward the liquid crystal filling region 3, and spacings between every two adjacent metal traces in the metal trace structure 4 are increased progressively by a linear increasing law or a nonlinear increasing law in a direction from the metal trace structure 4 toward the liquid crystal filling region 3.

It can be understood that the widths of the plurality of metal traces in the metal trace structure 4 can also be decreased progressively by a linearly decreasing law or a nonlinear decreasing law from a certain metal trace in the middle toward the liquid crystal filling region 3, or the spacings between every two adjacent metal traces in the metal trace structure 4 can be increased progressively by a linearly increasing law or a nonlinear increasing law from a certain metal trace in the middle toward the liquid crystal filling region 3 as long as the proportion of the light transmissive region L2 is gradually increased toward the liquid crystal filling region 3.

It can be understood that the shapes of the plurality of metal traces include, but are not limited to, a rectangle, an ellipse and the like.

In the first embodiment of the present invention, each of the plurality of metal traces in the metal trace structure 4 comprises a metal trace of a single layer structure, or a combination of a metal trace of a single layer structure and a metal trace of a laminated layers structure, or a metal trace of a laminated layers structure. For convenience of description, the following is exemplified by a rectangular metal trace. It should be noted that, in FIGS. 2 to 8, the liquid crystal filling region 3 is located on the right side of the metal trace structure 4.

(1) With a metal trace of a single layer structure:

As shown in FIG. 3, which is a schematic planar structure diagram of a metal trace structure 4 in an array substrate according to the first embodiment of the present invention, the spacings between every two adjacent metal traces are increased progressively by a linearly increasing law (a straight line) from some metal trace in the middle toward the liquid crystal filling region 3. At this time, the widths of the metal traces are constant, and by changing the spacings, the spacing adjacent to the liquid crystal filling region 3 is larger than the spacing in the middle, such as d3>d2>d1>d, and the UV light transmittance adjacent to the liquid crystal is improved.

As shown in FIG. 4, which is a schematic planar structure diagram of a metal trace structure 4 in an array substrate according to the first embodiment of the present invention, the spacings between every two adjacent metal traces are increased progressively by a nonlinear increasing law (a polyline) from some metal trace in the middle toward the liquid crystal filling region 3. At this time, the widths of the metal traces are constant, and by changing the spacings, the spacing adjacent to the liquid crystal filling region 3 is larger than the spacing in the middle, such as d2>d1>d, and the UV light transmittance adjacent to the liquid crystal can also be improved.

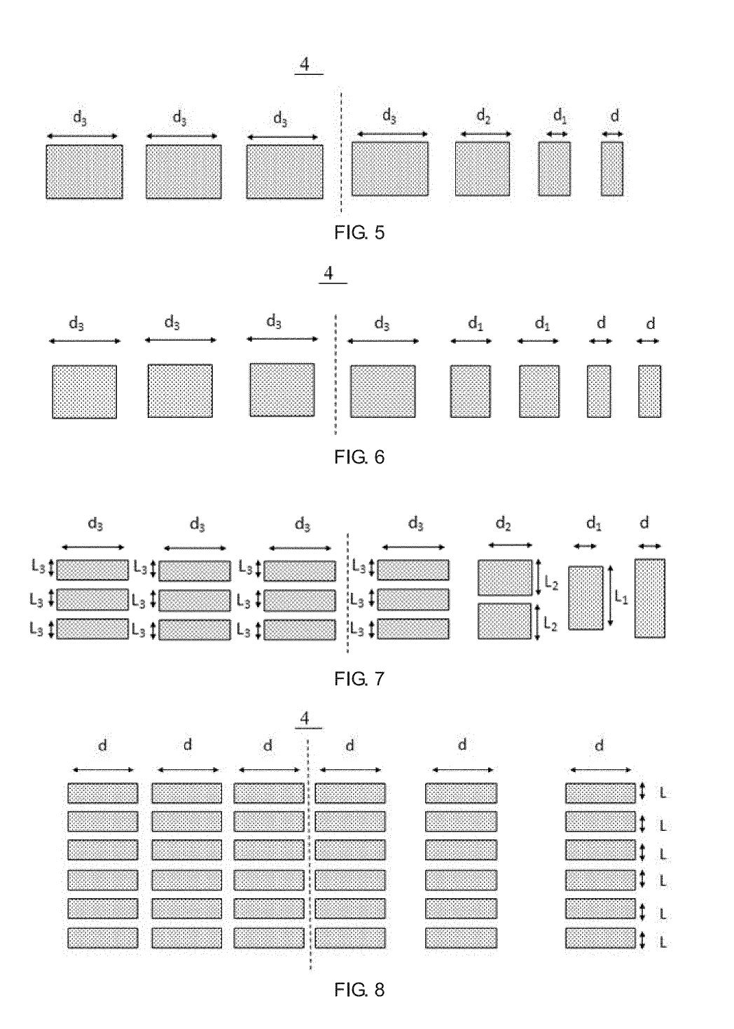

As shown in FIG. 5, which is one another schematic planar structure diagram of a metal trace structure 4 in an array substrate according to the first embodiment of the present invention, the widths of the plurality of metal traces are decreased progressively by a linearly increasing law (a straight line) from some metal trace in the middle toward the liquid crystal filling region 3. At this time, the spacings of the metal traces are constant, and by changing the widths, the width adjacent to the liquid crystal filling region 3 is smaller than the width in the middle, such as d3>d2>d1>d and the areas are changed, and the UV light transmittance adjacent to the liquid crystal can also be improved.

As shown in FIG. 6, which is one another schematic planar structure diagram of a metal trace structure 4 in an array substrate according to the first embodiment of the present invention, the widths of the plurality of metal traces are decreased progressively by a nonlinear increasing law (a polyline) from some metal trace in the middle toward the liquid crystal filling region 3. At this time, the spacings of the metal traces are constant, and by changing the widths, the width adjacent to the liquid crystal filling region 3 is smaller than the width in the middle, such as d3>d2>d1>d and the areas are changed, and the UV light transmittance adjacent to the liquid crystal can also be improved.

It should be noted that the spacing and the width of the plurality of metal traces in the metal trace structure 4 can also be changed at the same time to improve the UV light transmittance adjacent to the liquid crystal. The spacing progressively increasing change can be referred to the manner of FIG. 3 and FIG. 4. The width progressively decreasing change can be referred to the manner of FIG. 5 and FIG. 6.

(2) With a combination of a metal trace of a single layer structure and a metal trace of a laminated layers structure:

Such a combination structure can improve the UV light transmittance adjacent to the liquid crystal by referring to the foregoing various cases of the single layer structure (1), that is, the UV light transmittance adjacent to the liquid crystal can be improved by change of spacing or width.

As shown in FIG. 7, which is one another schematic planar structure diagram of a metal trace structure 4 in an array substrate according to the first embodiment of the present invention, a deformation of FIG. 5, the widths of the plurality of metal traces are decreased progressively by a linearly increasing law (a straight line) from some metal trace in the middle toward the liquid crystal filling region 3. At this time, the spacings of the metal traces are constant, and by changing the widths, the width adjacent to the liquid crystal filling region 3 is smaller than the width in the middle, such as d3>d2>d1>d and the areas are changed, and the UV light transmittance adjacent to the liquid crystal is improved.

(3) With a metal trace of a laminated layers structure:

Such a laminated layers structure can improve the UV light transmittance adjacent to the liquid crystal by referring to the foregoing various cases of the single layer structure (1), that is, the UV light transmittance adjacent to the liquid crystal can be improved by change of spacing or width.

As shown in FIG. 8, which is one another schematic planar structure diagram of a metal trace structure 4 in an array substrate according to the first embodiment of the present invention, a deformation of FIG. 3, the single layer structure in FIG. 3 is converted into the same laminated layers structure as in FIG. 8 to improve the UV light transmittance adjacent to the liquid crystal.

In the first embodiment of the present invention, the array substrate is a TFT substrate. Therefore, the main body 1 of the array substrate comprises a first substrate 11, a first metal layer 12, a gate insulating layer 13, an active layer 14, a second metal layer 15, a passivation layer 16 and a pixel electrode layer 17, which are sequentially disposed from bottom to top. Certainly, for the convenience of the process, the sealant material may be disposed on the array substrate, and thus the array substrate further comprises a sealant 5 being coated on the sealant coating region 2 of the main body 1 and covering the metal trace structure 4.

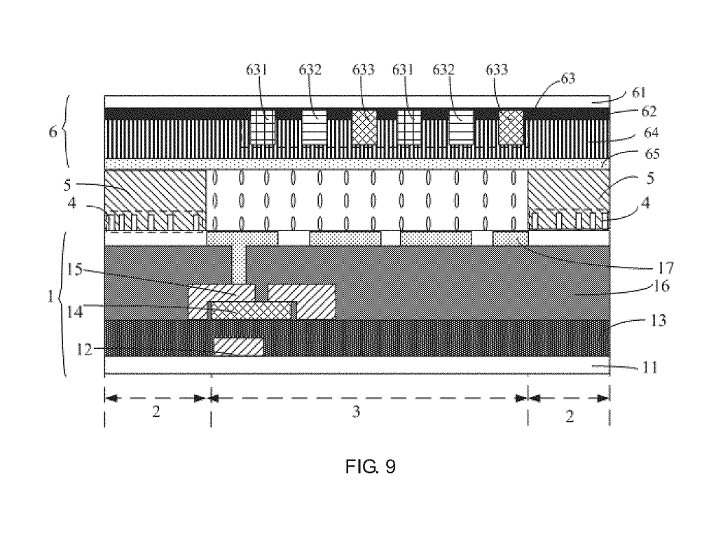

As shown in FIG. 9, in accordance with the array substrate provided in the first embodiment of the present invention, the second embodiment of the present invention further provides a display device including the array substrate 1 according to the first embodiment of the present invention and a color filter substrate 6. The array substrate in the second embodiment of the present invention has the same structure and connection relationship as the array substrate in the first embodiment of the present invention. For details, please refer to the related content of the array substrate in the first embodiment of the present invention, and therefore, no details are provided herein.

In the second embodiment of the present invention, the array substrate 1 is bonded to the color filter substrate 6 with the sealant 5 disposed thereon so that the liquid crystal filling region 3 thereon and the color filter substrate 6 are sealed to form a liquid crystal cell for filling liquid crystal molecules.

In the second embodiment of the present invention, the color filter substrate 6 comprises a second substrate 61, and a black matrix 62, a color filter layer 63, a protective layer 64 and a metal electrode layer 65 located on the second substrate 61. The color filter layer 61 comprises a red color resist layer 631, a green color resist layer 632 and a blue color resist layer 633.

In summary, the implementation of the embodiments of the present invention possesses the following beneficial result: in the case where the total designed width of the sealant coating region is limited, the proportion of the light transmissive region is improved by increasing the spacings of metal traces of the sealant adjacent to the liquid crystal (the spacings of the metal traces are increased progressively by a linear increasing law or a nonlinear increasing law in a direction from the metal trace structure toward the liquid crystal filling region) or reducing the widths of the metal traces adjacent to the liquid crystal (the widths of the metal traces are decreased progressively by a linear increasing law or a nonlinear increasing law in a direction from the metal trace structure toward the liquid crystal filling region). Thus, the UV light transmittance adjacent to the liquid crystal is improved to increase the curing rate of the sealant adjacent to the liquid crystal, so as to reduce the contamination of the liquid crystal by the incompletely cured sealant.

The above content with the specific preferred embodiments of the present invention is further made to the detailed description, the specific embodiments of the present invention should not be considered limited to these descriptions. Those of ordinary skill in the art for the present invention, without departing from the spirit of the present invention, can make various simple deduction or replacement, should be deemed to belong to the scope of the present invention.

What is claimed is:

1. An array substrate, comprising a main body, a sealant coating region formed on a periphery of the main body and used for sealant coating and a liquid crystal filling region located in a middle of the main body and surrounded by the sealant coating region; wherein
in the sealant coating region, a metal trace structure on the main body is provided, and the metal trace structure comprises a plurality of metal traces spaced apart; wherein the sealant coating region comprises light transmissive regions corresponding to gaps between the plurality of metal traces;
in a region of the sealant coating region adjacent to a side of the liquid crystal filling region, a proportion of the light transmissive region adjacent to the liquid crystal filling region is larger than a proportion of the light transmissive region away from the liquid crystal filling region; wherein the proportion of the light transmissive region is an area ratio of the light transmissive region to a corresponding sealant coating region.

2. The array substrate according to claim 1, wherein widths of the plurality of metal traces in the metal trace structure are decreased progressively by a linear decreasing law or a nonlinear decreasing law in a direction from the metal trace structure toward the liquid crystal filling region, and spacings between every two adjacent metal traces in the metal trace structure are equal.

3. The array substrate according to claim 2, wherein each of the plurality of metal traces in the metal trace structure comprises a metal trace of a single layer structure; or
each of the plurality of metal traces in the metal trace structure comprises a combination of a metal trace of a single layer structure and a metal trace of a laminated layers structure; or
each of the plurality of metal traces in the metal trace structure comprises a metal trace of a laminated layers structure.

4. The array substrate according to claim 3, further comprising a sealant being coated on the sealant coating region of the main body and covering the metal trace structure.

5. The array substrate according to claim 4, wherein the main body comprises a first substrate, a first metal layer, a gate insulating layer; an active layer, a second metal layer, a passivation layer and a pixel electrode layer, which are sequentially disposed from bottom to top.

6. An array substrate, comprising a main body, a sealant coating region formed on a periphery of the main body and used for sealant coating and a liquid crystal filling region located in a middle of the main body and surrounded by the sealant coating region; wherein
in the sealant coating region, a metal trace structure on the main body is provided, and the metal trace structure comprises a plurality of metal traces spaced apart; wherein the sealant coating region comprises light transmissive regions corresponding to gaps between the plurality of metal traces;
in a region of the sealant coating region adjacent to a side of the liquid crystal filling region, a proportion of the light transmissive region adjacent to the liquid crystal filling region is larger than a proportion of the light transmissive region away from the liquid crystal filling region; wherein the proportion of the light transmissive region is an area ratio of the light transmissive region to a corresponding sealant coating region;
wherein widths of the plurality of metal traces in the metal trace structure are equal, and spacings between every two adjacent metal traces in the metal trace structure are increased progressively by a linear increasing law or a nonlinear increasing law in a direction from the metal trace structure toward the liquid crystal filling region; or
the widths of the plurality of metal traces in the metal trace structure are decreased progressively by a linear decreasing law or a nonlinear decreasing law in a direction from the metal trace structure toward the liquid crystal filling region; and spacings between every two adjacent metal traces in the metal trace structure are increased progressively by a linear increasing law or a nonlinear increasing law in a direction from the metal trace structure toward the liquid crystal filling region.

7. The array substrate according to claim 6, wherein each of the plurality of metal traces in the metal trace structure comprises a metal trace of a single layer structure; or
each of the plurality of metal traces in the metal trace structure comprises a combination of a metal trace of a single layer structure and a metal trace of a laminated layers structure; or
each of the plurality of metal traces in the metal trace structure comprises a metal trace of a laminated layers structure.

8. The array substrate according to claim 7, further comprising a sealant being coated on the sealant coating region of the main body and covering the metal trace structure.

9. The array substrate according to claim 8, wherein the main body comprises a first substrate, a first metal layer, a gate insulating layer, an active layer, a second metal layer, a passivation layer and a pixel electrode layer; which are sequentially disposed from bottom to top.

10. A display device, comprising an array substrate and a color ter substrate; wherein
the array substrate comprises a main body, a sealant coating region formed on a periphery of the main body and used for sealant coating and a liquid crystal filling region located in a middle of the main body and surrounded by the sealant coating region; wherein
in the sealant coating region, a metal trace structure on the main body is provided, and the metal trace structure comprises a plurality of metal traces spaced apart; wherein the sealant coating region comprises light transmissive regions corresponding to gaps between the plurality of metal traces;
in a region of the sealant coating region adjacent to a side of the liquid crystal filling region, a proportion of the light transmissive region adjacent to the liquid crystal filling region is larger than a proportion of the light transmissive region away from the liquid crystal filling region; wherein the proportion of the light transmissive region is an area ratio of the light transmissive region to a corresponding sealant coating region.

11. The display device according to claim 10, wherein widths of the plurality of metal traces in the metal trace structure are decreased progressively by a linear decreasing law or a nonlinear decreasing law in a direction from the metal trace structure toward the liquid crystal filling region, and spacings between every two adjacent metal traces in the metal trace structure are equal.

12. The display device according to claim 11, wherein each of the plurality of metal traces in the metal trace structure comprises a metal trace of a single layer structure.

13. The display device according to claim 10, wherein widths of the plurality of metal traces in the metal trace structure are equal, and spacings between every two adjacent metal traces in the metal trace structure are increased progressively by a linear increasing law or a nonlinear increasing law in a direction from the metal trace structure toward the liquid crystal filling region.

14. The display device according to claim 13, wherein each of the plurality of metal traces in the metal trace structure comprises a combination of a metal trace of a single layer structure and a metal trace of a laminated layers structure.

15. The display device according to claim 10, wherein the widths of the plurality of metal traces in the metal trace structure are decreased progressively by a linear decreasing law or a nonlinear decreasing law in a direction from the metal trace structure toward the liquid crystal filling region, and spacings between every two adjacent metal traces in the metal trace structure are increased progressively by a linear increasing law or a nonlinear increasing law in a direction from the metal trace structure toward the liquid crystal filling region.

16. The display device according to claim 15, wherein each of the plurality of metal traces in the metal trace structure comprises a metal trace of a laminated layers structure.

17. The display device according to claim 10, wherein the color filter substrate comprises a second substrate, and a black matrix, a color filter layer and a metal electrode layer located on the second substrate.

18. The display device according to claim 17, wherein the color filter layer comprises a red color resist layer, a green color resist layer and a blue color resist layer.
